(19) United States
(12) Patent Application Publication
(10) Pub. No.: US 2024/0203687 A1
(43) Pub. Date: Jun. 20, 2024

(54) MULTI-BEAM PARTICLE MICROSCOPE WITH IMPROVED BEAM CURRENT CONTROL

(71) Applicant: Carl Zeiss MultiSEM GmbH, Oberkochen (DE)

(72) Inventors: Gero Storeck, Aalen (DE); Holger Kierey, Aalen (DE)

(21) Appl. No.: 18/405,813

(22) Filed: Jan. 5, 2024

Related U.S. Application Data
(63) Continuation of application No. PCT/EP2022/025309, filed on Jul. 5, 2022.

(30) Foreign Application Priority Data
Jul. 19, 2021 (DE) 10 2021 118 561.0

(51) Int. Cl. H01J 37/24; H01J 37/10; H01J 37/244

(52) U.S. Cl. CPC H01J 37/243; H01J 37/10; H01J 37/244; H01J 2237/0435; H01J 2237/24564

(57) ABSTRACT

A multi-beam particle microscope can provide improved beam current control. Excess electrons discharged from one or just a few regions of an absorber layer provided on a multi-aperture array can be measured via an ammeter. The measured currents can be used as controlled variables in a closed loop control. The measurement can be large-area and low-noise. The multi-aperture array can be specifically structured to also realize a direction sensitive detection, for example via a quadrant detector or a tertial detector.

### CROSS-REFERENCE TO RELATED APPLICATIONS

The present application is a continuation of, and claims benefit under 35 USC 120 to, international application PCT/EP2022/025309, filed Jul. 5, 2022, which claims benefit under 35 USC 119 of German Application No. 10 2021 118 561.0, filed Jul. 19, 2021. The entire disclosure of each these applications is incorporated by reference herein.

### FIELD

In general, the disclosure relates to multi-beam particle microscopes which operate using a plurality of individual particle beams. For example, the disclosure relates to a multi-beam particle microscope with an improved beam current control.

### BACKGROUND

With the continuous development of ever smaller and ever more complex microstructures such as semiconductor components, there can be a desire to develop and optimize planar production techniques and inspection systems for producing and inspecting small dimensions of the microstructures. By way of example, the development and production of the semiconductor components generally involves monitoring of the design of test wafers, and the planar production techniques generally involve a process optimization for a reliable production with a high throughput. Moreover, there have been recent demands for an analysis of semiconductor wafers for reverse engineering and for a customer-specific, individual configuration of semiconductor components. Therefore, there can be a desire for inspection mechanism which can be used with a high throughput for examining the microstructures on wafers with a great accuracy.

Typical silicon wafers used in the production of semiconductor components have diameters of up to 300 mm. Each wafer is subdivided into 30 to 60 repeating regions (“dies”) with a size of up to 800 mm². A semiconductor apparatus comprises a plurality of semiconductor structures, which are produced in layers on a surface of the wafer by planar integration techniques. Semiconductor wafers typically have a plane surface on account of the production processes. The structure sizes of the integrated semiconductor structures in this case extend from a few μm to the critical dimensions (CD) of 5 nm, wherein the structure dimensions will become even smaller in the near future; in future, structure sizes or critical dimensions (CD) are expected to be less than 3 nm, for example 2 nm, or even under 1 nm. In the case of the aforementioned small structure sizes, defects of the size of the critical dimensions is to be identified quickly in a very large area. For several applications, the specification on the accuracy of a measurement provided by an inspection device are even higher, for example by a factor of two or one order of magnitude. By way of example, a width of a semiconductor feature is to be measured with an accuracy of below 1 nm, for example 0.3 nm or even less, and a relative position of semiconductor structures is to be determined with a superposition accuracy of below 1 nm, for example 0.3 nm or even less.

The MSEM, a multi-beam scanning electron microscope, is a relatively new development in the field of charged particle systems (charged particle microscopes, CPMs). By way of example, a multi-beam scanning electron microscope is disclosed in U.S. Pat. No. 7,244,949 B2 and in US 2019/0355544 A1. In the case of a multi-beam electron microscope or MSEM, a sample is irradiated simultaneously with a plurality of individual electron beams, which are arranged in a field or raster. By way of example, 4 to 10,000 individual electron beams can be provided as primary radiation, with each individual electron beam being separated from an adjacent individual electron beam by a pitch of 1 to 200 micrometers. By way of example, an MSEM has approximately 100 separated individual electron beams (“beamlets”), which for example are arranged in a hexagonal raster, with the individual electron beams being separated by a distance of approximately 10 μm. The plurality of charged individual particle beams (primary beams) are focused, individually in each case, on a surface of a sample to be examined by way of common large-field optics including, inter alia, a common objective lens. By way of example, the sample can be a semiconductor wafer which is fastened to a wafer holder that is assembled on a movable stage. During the illumination of the wafer surface with the charged primary individual particle beams, interaction products, for example secondary electrons or backscattered electrons, emanate from the surface of the wafer. Their respective start points correspond to those locations on the sample on which the plurality of primary individual particle beams are focused in each case. The amount and the energy of the interaction products depends inter alia on the material composition and the topography of the wafer surface. The interaction products form a plurality of secondary individual particle beams (secondary beams), which are collected by the common objective lens and which are incident on a detector arranged in a detection plane as a result of a projection imaging system of the multi-beam inspection system. The detector comprises a plurality of detection regions, each of which comprises a plurality of detection pixels, and the detector captures an intensity distribution for each of the secondary individual particle beams. An image field of for example 100 μm×100 μm is obtained in the process.

Certain known multi-beam electron microscopes can comprise a sequence of electrostatic and magnetic elements. At least some of the electrostatic and magnetic elements are adjustable in order to adapt the focus position and the stigmation of the plurality of charged individual particle beams. Certain known multi-beam systems with charged particles moreover can comprise at least one cross-over plane of the primary or the secondary charged individual particle beams. Moreover, such systems can comprise detection systems to make the adjustment easier. Such multi-beam particle microscopes can comprise at least one beam deflector (“deflection scanner”) for collective scanning of a region of the sample surface via the plurality of primary individual beams in order to obtain an image field of the sample surface. Further details regarding a multi-beam electron microscope and a method for operating same are described in the German patent application with the application number 102020206739.2, filed on May 28, 2020, the disclosure of which is incorporated in full in this patent application by reference.

In general, as the demands on the imaging quality increase, so do the demands on the multi-beam particle microscope used for imaging. Stable operating parameters are generally to be considered for high-quality recordings. One of these is the beam current intensity of the individual particle beams used to scan a sample surface.

For a uniform beam current intensity of the individual particle beams, the emission characteristic of the particle beam source is to be considered, more precisely a uniformity of the emission characteristic over the entire utilized emission angle. When using relatively large emission angles, the emission characteristic of particle sources, e.g., of thermal field emission (TFE) sources, is often no longer uniform throughout. Accordingly, the irradiance at a first multi-aperture plate in a corresponding particle beam system is also often no longer uniform throughout and there are relatively large variations in the current densities in different individual beams. However, in the case of multi-particle inspection systems, it is desirable in a system that there is only a small variation in the current intensities between the various individual beams, which is typically less than a few percent or even less than one percent, so that all individual image fields of the multi-image field are scanned with an equivalent number of particles or electrons. By way of example, this is a precondition to obtain individual images with approximately the same brightness. The obtainable resolution of the individual images also depends on the individual beam current.

There are options for an individual adjustment of the beam current for individual particle beams. One option in this respect is disclosed by DE 10 2018 007 652 A1, the disclosure of which is incorporated in this patent application in full by reference.

The emission characteristic of the particle source also changes slowly over time; it may as a whole exhibit a drift behaviour. A particle source or tip may age; by way of example, it may lose brightness. The brightness of the images, in turn, correlates with the brightness or luminance of the source. If the source loses brightness, this can also apply to the image brightness. Furthermore, by way of example, a particle beam originally emitted by the source may change its direction. It is therefore generally desirable to take measures that allow for providing a more stable and uniform beam current when scanning a sample with a plurality of individual charged particle beams or beamlets.

This holds for example when the desired properties for a stable beam current become even higher: Normally, a beam current stability of a multi-beam particle microscope was regarded as sufficiently stable when a relative variation of the beam current with respect to a reference beam current was ≤10% or ≤5% for one hour. For future measurement tasks, such a stability is not regarded as sufficient any more: Higher desired properties have to be fulfilled and a relative beam current variation with respect to a reference beam current of a multi-beam charged particle microscope is to be equal to or smaller than 1% for at least one month!

Several ideas for measuring or monitoring a beam current and for respectively controlling the beam current have been previously disclosed. However, with regard to the higher desired properties for beam current stability, it has turned out that the already existing solutions are not sufficient and are to be improved.

US 2020/0312619 A1 discloses systems and methods of measuring a beam current in a multi-beam apparatus which can be a multi-beam particle microscope. The multi-beam particle microscope includes a charged particle beam source configured to generate a primary charged-particle beam, and a multi-aperture array. The multi-aperture array comprises a plurality of apertures configured to form a plurality of beamlets from the primary charged-particle beam and a detector including circuitry to detect a current of at least a portion of the primary charged-particle beam irradiating the multi-aperture array. In more detail, a plurality of small detectors with circuitry is provided within small additional holes provided on the upper side of the multi-aperture array. The holes can be associated with certain apertures and are thus small and provided near certain apertures. They are provided within the array of apertures and they are provided directly at the border of the array, touching the theoretical circumferential zone of the array. Examples for the detectors with circuitry are a Faraday cup, a diode, an array of diodes, a scintillator, or a photo-multiplier tube. The detector with circuitry is used to monitor a current incident on the detector and it is possible to determine a total current from the measured values. Furthermore, it is possible to detect changes in the current, such as a beam position, a beam diameter, the beam current itself, the beam current density and the uniformity of the beam current density. These changes can be corrected by controlling the extraction voltage, controlling the acceleration voltage, controlling beam deflection voltages, etc.

US 2020/0312619 A1 can exhibit several drawbacks: The overall sensitivity of the beam current detection can be limited due to the small area that is used for a single detection. Assuming that the surface area of a detector is comparable to the area of an aperture generating a beamlet, the beam current measured with the detector can be of the same order of magnitude as the single beam current passing through an associated aperture. Typically, this single beam current is in the order of a few hundred picoampere which is rather low. Detecting variations much smaller than 1% can therefore be even more difficult, and the signal-to-noise ratio of a detector with such a small entry surface can be comparatively high. Furthermore, the borders of the detector integrated within holes in multi-aperture plate can cause problems due to accumulated charges which might negatively influence the beam directions and beam quality of the beamlets. Still further, manufacturing of the small detectors can be complicated. Therefore, overall, the detection system according to US 2020/0312619 A1 may not suited for measurement tasks involving a beam current stability better than 1% for one month or even longer.

U.S. Pat. No. 6,969,862 B2 discloses a beam current detection for lithography systems. It discloses a multi-beam apparatus comprising a charged-particle source configured to generate a primary charged-particle beam and an aperture array. The aperture array comprises a plurality of apertures configured to form a plurality of beamlets from the primary charged-particle beam and a detector coupled to circuitry and configured to detect a current of at least a portion of the primary charged-particle beam irradiating the aperture array, wherein the detector is disposed on a beam exit side of the aperture array with respect to the primary charged-particle beam. The multi-beam apparatus according to U.S. Pat. No. 6,969,862 B2 is therefore very similar to the multi-beam apparatus according to US 2020/0312619 A1 cited above. A difference between both publications is that the detector is positioned on the beam entrance side according to US 2020/0312619 A1, but on the beam exit side according to U.S. Pat. No. 6,969,862 B2. However, the measurement concept is the same in both cases, since the detected beam current enters a hole specifically provided on the beam entrance side of the multi-aperture array in both cases and is then directly detected with the detector with circuitry. Consequently, the detection system according to U.S. Pat. No. 6,969,862 B2 may also not suited for measurement tasks involving a beam current stability better that 1% for one month or even longer.

U.S. Pat. No. 7,388,214 B2 discloses a charged particle beam exposure apparatus which splits a charged-particle beam from a charged-particle beam source into a plurality of charged-particle beams by a plurality of apertures formed in an aperture array to expose a wafer using the plurality of charged-particle beams. The apparatus includes a stage on which the wafer is loaded, the wafer being irradiated with the plurality of charged-particle beams, which have been passed through the apertures of the aperture array, a plurality of detection electrodes which detect intensities of the plurality of charged-particle beams passing through the plurality of apertures of the aperture array to expose the wafer with the plurality of charged-particle beams, the plurality of detection electrodes being formed on the charged-particle beam source side of the light-shielding peripheral regions of the plurality of apertures of the aperture array, and a grid array (comprising grid electrodes) which adjusts the intensities of the plurality of charged-particle beams on the basis of detection results obtained by the plurality of detection electrodes. The detection system according to U.S. Pat. No. 7,388,214 B2 may also not suited for measurement tasks involving a beam current stability better than 1% for one month or even longer. The detection area is once again very small since the detection electrodes provided on electrode pads can be assigned to one aperture each, and thus a signal-to-noise ratio of a beam current measurement can be comparatively small. An assignment of several detection electrodes to one pad is also disclosed and it is taught that this would increase the detection accuracy. However, on the other hand, the latter assignment can mean that the specific control using grid electrodes becomes less precise since a common wiring of the pads results in the same control voltages applied to the grid electrodes. Therefore, the area that is used for detection purposes can stay small overall as a compromise. Furthermore, there can be a risk that any active influence on the beamlets using charges on the multi-aperture array further influences the beamlet quality. With regard to manufacturing aspects, the solution of U.S. Pat. No. 7,388,214 B2 is also rather complicated.

U.S. Pat. No. 9,607,806 B2 discloses a multi-beam lithography system with detectors for beam control provided at specific positions on top of a multi-aperture array. The detectors can measure a beam current when the beams are deflected or blanked.

U.S. Pat. No. 6,617,587 B2 discloses a multi-beam lithography system. It has a tip regulation circuit with a current collection area on a single aperture plate which is part of the electrode gun itself and is provided for each of the plurality of beams separately.

U.S. Pat. No. 5,111,053 A discloses controlling a liquid metal ion source by analogue feedback and digital CPU control. The document relates to a single beam system. A monitoring electrode is applied for measuring the beam current and an extraction voltage of the source is adjusted.

U.S. Pat. No. 7,091,486 B1 first describes a conventional technique for correcting beam current fluctuations for a single beam system. The described conventional technique for correcting beam current fluctuations uses a circuit connected to the beam-limiting aperture to measure an electrical current from the aperture. This electrical current is due to the electrons being absorbed by the aperture. From the current measured, a beam current may be inferred. Changes in the current measured are used to infer changes in the beam current. The conventional technique is taught to be suitable to detect fluctuations only within a limited bandwidth of frequencies. For example, detecting high-frequency (for example, above a few kilohertz) fluctuations is said to be problematic. This bandwidth limitation is said to appear due to the low current levels and high stray capacitance in the conventional technique. Therefore, U.S. Pat. No. 7,091,486 B1 teaches to use a high-speed detector mounted above the aperture to collect and measure secondary and/or backscattered electrons. The secondary and/or backscattered electrons are emitted due to the impingement of part of the primary beam (the part being blocked) onto the aperture. High-speed electron detectors include, for example, Everhart-Thornley detectors, PIN diode based detectors, and microchannel plate detectors.

### SUMMARY

The present disclosure seeks to provide a multi-beam particle microscope with improved beam current stability. It is desired to be suited for measurement tasks involving a beam current stability better than 1% for one month or even longer. Features to implement a respective feedback control are desirably easy to manufacture and to implement.

According to a first aspect, the disclosure provides a multi-beam particle microscope, comprising the following: a beam generating system comprising a particle source, an extractor electrode and an anode and configured to produce a first charged particle beam; a multi-beam generator having a multi-aperture array, the multi-beam generator being configured to produce a first field of a plurality of first individual charged particle beams from the first charged particle beam, the multi-aperture array comprising on its upper side an absorber layer which absorbs electrons, the absorber layer being connected to at least one ground electrode to discharge excess electrons; a first beam current measuring mechanism which is configured to measure over a large area at least the discharged excess electrons generated by charged particles impinging the multi-aperture array in an outer region around all of the openings in the multi-aperture array; a condenser lens system arranged between the beam generating system and the multi-beam generator; a first particle optical unit with a first particle optical beam path, configured to direct the generated first individual particle beams at a sample such that the first individual particle beams strike the sample at incidence locations, which form a second field; a detection system; a second particle optical unit with a second particle optical beam path, which is configured to image second individual particle beams, which emanate from the incidence locations in the second field, onto the detection system; a particle optical objective lens, through which both the first and the second individual particle beams pass; a beam switch, which is arranged in the first particle optical beam path between the multi-beam generator and the objective lens and which is arranged in the second particle optical beam path between the objective lens and the detection system; and a controller which is configured to control the beam generating system, the condenser lens system, the particle optical objective lens, the first particle optical unit, the second particle optical unit, and the detection system, and with the controller being configured for controlling the beam generating system on the basis of the measurement via the first beam current measuring mechanism, and/ or with the controller being configured for controlling the condenser lens system on the basis of the measurement via the first beam current measuring mechanism.

The individual charged particle beams can be, e.g., electrons, positrons, muons or ions or other charged particles.

The multi-aperture array can be an array arranged as a first multi-aperture array downstream of a condenser lens system in the particle optical beam path of the multi-beam particle microscope. This multi-aperture array can be the array which divides a first charged particle beam into a plurality of individual charged particle beams. In this case, the multi-aperture array can be a constituent part of what is known as the micro-optics, which can consist of or comprise a sequence of a plurality of multi-aperture plates or multi-aperture arrays (the two expressions being used as synonyms within the present patent application). For a good image quality in this context, in general, the first charged particle beam that emanates from a particle source or a tip has to be incident uniformly on the multi-aperture array as perpendicularly as possible, for example, and also illuminate the latter as uniformly or as centered as possible. Then, it is possible to ensure that the beam current of the individual particle beams that pass through the multi-aperture array is sufficiently uniform in the individual particle beams. A uniform illumination can be achieved not only in the case of a telecentric incidence of the first charged particle beam on the multi-aperture array but also in the case of a divergent or convergent incidence, and in any case whenever the central beam axis is aligned perpendicular to the surface of the multi-aperture array. Here, the openings in the multi-aperture array can be circular but may have any other shape as well. Optionally, the openings in the multi-aperture array have a regular arrangement, for example a rectangular, square or hexagonal arrangement. Optionally, 3n(n−1)+1 openings are provided in the case of a hexagonal arrangement, where n is any natural number.

The multi-aperture array or multi-aperture plate can comprise on its upper side an absorber layer which can absorb electrons. Optionally, the absorber layer is provided on substantially the entire surface of the multi-aperture array (except for the apertures, of course) and therefore not only on an inner region comprising the apertures, but also in an outer region around all of the openings in the multi-aperture array. Also in existing multi-beam particle microscopes such an absorber layer can be provided. It can help ensure that no charges are accumulated on the surface of the multi-aperture array which would otherwise seriously deteriorate the beam quality of the first individual particle beams.

This measuring system may be calibrated, for example by virtue of the individual particle beams being measured using a displaceable stage and, for example, a Faraday cup thereon. Other embodiment variants and calibration methods are also conceivable.

According to the present disclosure, a first beam current measuring mechanism can be provided that is configured to measure over a large area at least the discharged excess electrons generated by charged particles impinging the multi-aperture array in an outer region around all of the openings in the multi-aperture array. Contrary to certain known multi-beam particle apparatuses, the measurement takes place over a large area and not within a small area typically used when separate detectors are placed on the multi-aperture array. Enlarging the area significantly can improve the signal-to-noise ratio during detection. Furthermore, surprisingly, measurements of the inventors have shown that any variations in the signal gained by a measurement over a large area in the outer region around all of the openings in the multi-aperture array still reflect beam current variations of individual particle beams. Measuring over a large area is thus no averaging that might cover bigger fluctuations in the beam current of individual charged particle beams. This finding is to be considered and is a change of concept compared to the state of the art where the main focus is put on measuring the beam current as precisely as possible for each individual particle beam separately. Surprisingly, such a separate measurement for each individual particle beam is not necessary.

Furthermore, the first beam current measuring mechanism according to the present disclosure does not require a separate detection device that has to be integrated on the multi-aperture array as such, no specific circuitry is to be provided. The solution according to the present disclosure is therefore very simple and significantly facilitates manufacturing the multi-aperture array as such. Any detection device, typically an ammeter and in particular a picoamperemeter, can be provided distant from the multi-aperture array. It is not necessary to provide the ammeter inside the vacuum provided inside the multi-beam particle microscope, but the ammeter can be provided outside the vacuum.

Furthermore, the measurement concept differs from the measurement concepts applied to multi-beam apparatuses according to the state of the art: According to certain known systems, the particles that are measured with the separately provided detectors on the multi-aperture array, are the particles that impinge on the multi-aperture array or more precisely impinge at positions where the detectors are provided. In contrast thereto, according to the present disclosure, the excess electrons that are measured are at least not directly the impinging charged particles, but can be transported and “converted”; still they are a measure of the impinging charged particles. This becomes clear when the multi-beam particle microscope operates with ions and not with electrons. In general, ions are too big to be absorbed in the absorber layer, but they adhere to the surface of the absorber layer. The ions give up electrons and these electrons can be transported and discharged or an equivalent number of already present electrons can be discharged

According to the disclosure at least the discharged excess electrons generated by charged particles impinging the multi-aperture array in an outer region around all of the openings in the multi-aperture array are measured over a larger area. The outer region around the openings in its entirety provides such a large area. Parts of the outer region can also provide a large area and so the improved signal-to-noise ratio for detection purposes can be achieved. Furthermore, measurements based on impinging particles in the outer region can indicate a positional shift of the entire beam cone of the first charged particle beam.

According to an embodiment, the first beam current measuring mechanism is configured to also measure the discharged excess electrons generated by charged particles impinging the multi-aperture array in an inner region comprising the openings in the multi-aperture array. The measurement of the excess electrons originating from the inner region and from the outer region can be carried out with one ammeter as an overall excess electron measurement. The interaction area for the measurement is then maximized and the signal-to-noise ratio is best. However, then, positional deviations of the entire first charged particle beam cannot be detected separately. However, this embodiment is relatively simple and can be implemented in already existing systems.

The first beam current measuring mechanism according to the present disclosure can then be implemented as control loops in general already known from the state of the art. The controller can for example be configured for controlling the beam generating system on the basis of the measurement via the first beam current measuring mechanism. Additionally or alternatively, the controller can be configured for controlling the condenser lens system on the basis of the measurement via the first beam current measuring mechanism. Other kinds of control implementation are also possible. The beam current measuring mechanism can be calibrated, for example by virtue of the individual particles beams being measured using a displaceable stage and, for example, a Faraday cup placed thereon. Other embodiment variants and calibration methods are also conceivable.

According to an embodiment, the absorber layer on the multi-aperture array is structured into exactly two separate regions that are isolated from one another, each region being connected to ground, wherein the first region is an inner region comprising the openings of the multi-aperture array and wherein the second region is the outer region around all of the openings in the multi-aperture array, and wherein the first beam current measuring mechanism is configured to measure the excess electrons discharged from the outer region, only. Optionally, the inner region and the outer region are complementary regions on the multi-aperture array. In other words, the entire surface of the multi-aperture array consists of the inner region and of the outer region. Measuring the excess electrons discharged from the outer region is sufficient for measuring and thus controlling fluctuations in the beam current of the individual charged particle beams. The inner region is not at all disturbed by any measurement or any structuring of the absorber layer and thus the beam quality of the individual particle beams can be kept at its best.

According to an embodiment, the absorber layer on the multi-aperture array is structured into at least two separate regions that are isolated from one another, each region being connected to ground, and the first beam current measuring mechanism is configured to measure over a large area the excess electrons discharged from each region separately. Structuring of the absorber layer is therefore limited to such segmentations that still result in sufficiently large separate regions. This can be desirable in order to ensure a good signal-to-noise ratio of the measurement. According to an embodiment, the overall structuring divides the absorber layer into five or six separate regions at maximum.

According to an embodiment, the absorber layer is structured into an inner region comprising the openings of the multi-aperture array and the outer region around all of the openings in the multi-aperture array. The outer region is further structured into four separate regions arranged to form a direction indicating quadrant detector and the first beam current measuring mechanism is configured to measure over a large area the excess electrons discharged from each quadrant separately. Optionally, the inner region is not structured at all, but is left totally undisturbed. Excess electrons discharged from the inner region can be optionally measured. The term quadrant detector indicates the overall arrangement of the separate regions that is suited for indicating a direction of a migration of the beam cone impinging the multi-aperture array. Optionally, the size of each quadrant is chosen to be approximately the same; however, certain deviations can be advantageous depending on the concrete arrangement of the openings in the multi-aperture plate generating a certain geometrical shape of the envelope around the openings. This envelope can define the borderline between the inner region and the outer region and can be used for the structuring and isolation.

According to an alternative embodiment, the absorber layer is structured into the inner region and the outer region, wherein the outer region is further structured into three separate regions arranged to form a direction indicating tertial detector and a first beam current measuring mechanism is configured to measure the excess electrons discharged from each tertial separately. The arrangement of the three separate regions of the tertial detectors is inspired by a triangle arrangement of separate detection areas. Following a calibration process, any deviation detected via one of the three separate regions can already indicate a positional deviation and in general allows for analyzing the kind of positional deviation. The use of the direction indicating tertial detector is advantageous with respect to the further limited number of structures/separations of the regions and therefore further minimizes any influence on the beam current quality by accumulated charges on the surface of the multi-aperture array. Optionally, the inner region is not structured at all, but is left totally undisturbed. Excess electrons discharged from the inner region can optionally be measured.

According to an embodiment of the present disclosure, the multi-beam particle microscope furthermore comprises a double deflector in the region of the condenser lens system, wherein the controller of the multi-beam particle microscope is furthermore configured to control the double deflector on the basis of the measurement via the first beam current measuring mechanism. The double deflector can be an electrostatic double deflector which can be operated fast compared to a magnetic double deflector. However, also a magnetic double deflector can be implemented. The double deflector can shift the entire first charged particle beam in parallel and can thus correct a positional deviation of the beam cone impinging on the multi-aperture array.

In general, the first beam current measuring mechanism can comprise one or more constituent parts. According to a very elegant and simple embodiment, the first beam current measuring via comprises only one constituent part. In the case of several constituent parts, these constituent parts can be identical, but they can also differ from one another.

According to an embodiment, the first beam current measuring via comprises at least one ammeter, for example a picoamperemeter. A picoamperemeter is relatively sensitive and can detect already very small variations in the provided excess electrons being a measure for the beam current.

According to an embodiment, at least 60% of the beam current reaching the multi-aperture array is used for the beam current measurement. This can help ensure a good signal-to-noise ratio since a large area measurement is carried out.

According to an embodiment, at least 90%, such as at least 95%, of the beam current reaching the multi-aperture array is used for the beam current measurement. The aforementioned values are normally achieved when the entire surface of the multi-aperture array is provided with the absorber layer and all excess electrons discharged to be transported to the ground electrode are measured. This can be done using one measurement device, such as a picoamperemeter, or by using several measurement devices, for example several picoamperemeters.

According to an embodiment, an active beam measurement surface of the absorber layer absorbing charged particles and discharging electrons therefrom for the beam current measurement is at least 60% of the entire surface of the multi-aperture array. Optionally, the active beam measurement surface is at least 90%, such as at least 95% of the entire surface of the multi-aperture array. There exists a difference between making reference to the active beam measurement surface on the one hand and making reference to the beam current reaching the multi-aperture array on the other hand: the active beam measurement surface is fixed by design, say by the provision of the absorber layer and the connection to ground via an ammeter, for example. In contrast thereto, the ratio of beam current reaching the multi-aperture array depends on the operational setting of the multi-beam particle microscope, for example it depends on the set beam diameter of the first charged particle beam. In any case, the above-mentioned embodiments guarantee that the measurement via the first beam current measuring via is carried out over a large area and therefore ensures a good signal-to-noise ratio.

According to an embodiment, an average single beam current of the plurality of the first individual particle beams is equal to or less than 1/100 of the beam current entirely measured by the first beam current measuring via, optionally the averaged single beam current of the plurality of the first individual particle beams is equal to or less than 1/500, such as equal to or less than 1/1000 of the beam current entirely measured by the first beam current measuring via. Therefore, the signal that is generated is much bigger than the single beam current which contributes to the desired very good signal-to-noise ratio. To give an example, a typical single beam current is in the order of a few hundred picoampere, for example 500 or 600 or 700 picoampere. The entire beam current measured via the excess electrons is exemplarily in the range of 500, 600 or 700 nanoampere. However, the single beam current as well as the overall current generated by the measured excess electrons can be bigger or smaller, for example only a few tens picoampere for a single beam current and only a few tens nanoampere for the excess electrons. However, a larger single beam current up to a few nanoampere is also possible, so is a beam current of a few microampere measured via the excess electrons.

According to an embodiment, the absorber layer is an absorber coating and/or the absorber layer comprises or consists of any one of the following: gold, silver, titanium, platinum. These are relatively good conductors and relatively insensitive to oxidation. In general, noble metals can be used.

According to an embodiment, the multi-aperture array is arranged as a first multi-aperture array downstream of the condenser lens system and is the array which divides the first charged particle beam into the plurality of first individual particle beams. Alternatively, the multi-aperture array is not arranged as the first multi-aperture array downstream of the condenser lens system. This variant can typically occur when a sequence of aperture plates, in particular a sequence of multi-aperture arrays, is provided.

According to an embodiment, the controller is configured for controlling the beam generating device by setting a voltage supplied to the extractor electrode. This kind of control is in general already known.

According to an embodiment, the controller is configured for controlling the beam generating device by setting a temperature of the particle source, in particular by setting a heating current or heating voltage. This kind of control can be a little slower than for example setting the voltage supplied to the extractor electrode; however, it has turned out that this kind of control is also sufficient and furthermore easy to implement, already during switching on and off procedures.

According to a second aspect of the disclosure, the latter relates to a multi-beam particle microscope, comprising the following: a beam generating system comprising a particle source, an extractor electrode and an anode and configured to produce a first charged particle beam; a multi-beam generator having a pre-aperture plate and a multi-aperture array, the multi-beam generator being configured to produce a first field of a plurality of first individual charged particle beams from the first charged particle beam, the multi-aperture array being arranged downstream and close to the pre-aperture plate, the multi-aperture array comprising on its upper side an absorber layer which absorbs charged particles, the absorber layer being connected to at least one ground electrode to discharge excess electrons, the pre-aperture plate comprising on its upper side a pre-aperture plate absorber layer which absorbs charged particles, the pre-aperture plate absorber layer being connected to at least one ground electrode to discharge excess electrons; a first beam current measuring via which is configured to measure at least the discharged excess electrons generated by charged particles impinging the pre-aperture plate; a condenser lens system arranged between the beam generating system and the multi-beam generator; a first particle optical unit with a first particle optical beam path, configured to direct the generated first individual particle beams at a sample such that the first individual particle beams strike the sample at incidence locations, which form a second field; a detection system; a second particle optical unit with a second particle optical beam path, which is configured to image second individual particle beams, which emanate from the incidence locations in the second field, onto the detection system; a particle optical objective lens, through which both the first and the second individual particle beams pass; a beam switch, which is arranged in the first particle optical beam path between the multi-beam particle source and the objective lens and which is arranged in the second particle optical beam path between the objective lens and the detection system; and a controller which is configured to control the beam generating system, the particle optical objective lens, the first particle optical unit, the second particle optical unit, and the detection system, and with the controller being configured for driving of the beam generating system on the basis of the measurement via the first beam current measuring via; and/ or with the controller being configured for controlling the condenser lens system on the basis of the measurement via the first beam current measuring via.

As already mentioned above, a multi-beam generator can comprise a sequence of aperture plates and multi-aperture plates which can be part of the so-called micro optics. One feature according to the disclosure according to the first aspect is that excess electrons generated by impinging particles in the outer region of the multi-aperture array can be used for the beam current measurement. Of course, it also possible to place a pre-aperture plate, and this via a plate with just one single central opening, just above/upstream the outer region of the multi-aperture array and to carry out the measurements based on excess electrons discharged from this pre-aperture plate. The embodiment variants as described with respect to the first aspect of the disclosure can be transferred to the embodiment variant according to the second aspect of the disclosure. In particular, the absorber layer provided on the pre-aperture plate can be structured into regions that allow for a measurement over a large area as explained in further detail with respect to the first aspect of the disclosure. Of course, it is also possible to additionally carry out a measurement of the excess electrons generated by the charged particles impinging on the multi-aperture array; normally this will coincide with measurements in the inner area of the multi-aperture array as described above with respect to the first aspect of the disclosure. The embodiments of the disclosure according to the first aspect and according to the second aspect can be combined fully or in part with one another, as long as no technical contradictions occur.

### BRIEF DESCRIPTION OF THE DRAWINGS

In this context, the disclosure will be understood even better with reference to the accompanying figures, in which:

FIG. 1: shows a schematic representation of a multi-beam particle microscope (MSEM);

FIG. 2: schematically illustrates a beam current measurement;

FIGS. 3A-3B: schematically illustrate multi-aperture arrays with an absorber layer on its upper side;

FIG. 4: compares a single beam current and a current generated by excess electrons discharged from an absorber layer of a multi-aperture array;

FIG. 5: schematically illustrates another beam current measurement;

FIG. 6: schematically illustrates a quadrant detector;

FIG. 7: schematically illustrates another quadrant detector;

FIG. 8: shows a schematic representation of an adjustment of the beam cone of the illuminating beam upon incidence on a multi-aperture array;

FIG. 9: shows a schematic representation of an electrostatic double deflector in the region of a condenser lens system;

FIG. 10: schematically shows a multi-beam particle microscope having closed-loop beam current control via and compensators that are controlled via a controller;

FIG. 11: schematically shows details about a beam current control;

FIG. 12: schematically illustrates details of another beam current control based on a measurement of X-rays; and

FIG. 13: schematically illustrates a beam current measuring via using X-rays converted into NIR radiation.

### DETAILED DESCRIPTION

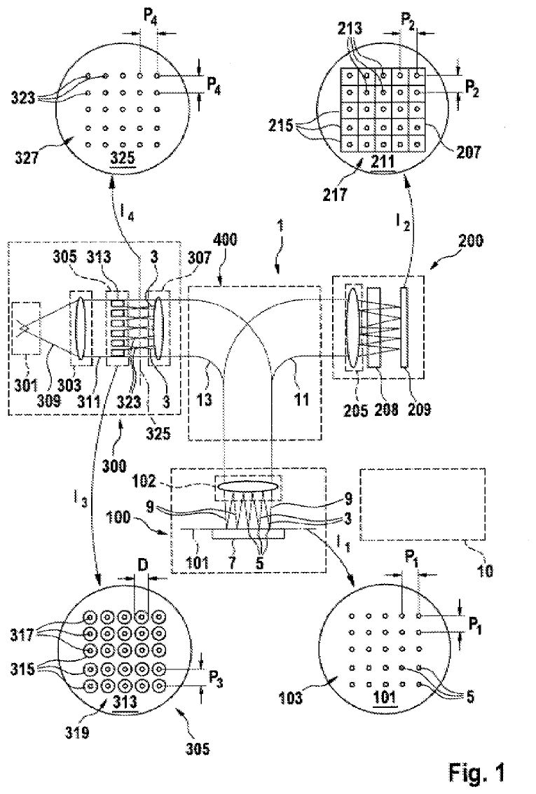

FIG. 1 is a schematic representation of a particle beam system 1 in the form of a multi-beam particle microscope 1, which uses a plurality of particle beams. The particle beam system 1 generates a plurality of particle beams which strike an object to be examined in order to generate there interaction products, e.g., secondary electrons, which emanate from the object and are subsequently detected. The particle beam system 1 is of the scanning electron microscope (SEM) type, which uses a plurality of primary particle beams 3 which are incident on a surface of the object 7 at a plurality of locations 5 and generate there a plurality of electron beam spots, or spots, that are spatially separated from one another. The object 7 to be examined can be of any desired type, e.g., a semiconductor wafer or a biological sample, and comprise an arrangement of miniaturized elements or the like. The surface of the object 7 is arranged in a first plane 101 (object plane) of an objective lens 102 of an objective lens system 100.

The enlarged excerpt I1 in FIG. 1 shows a plan view of the object plane 101 having a regular rectangular field 103 of incidence locations 5 formed in the first plane 101. In FIG. 1, the number of incidence locations is 25, which form a 5×5 field 103. The number 25 of incidence locations is a number chosen for reasons of simplified illustration. In practice, the number of beams, and hence the number of incidence locations, can be chosen to be significantly greater, such as, for example, 20×30, 100×100 and the like.

In the depicted embodiment, the field 103 of incidence locations 5 is a substantially regular rectangular field having a constant pitch P1 between adjacent incidence locations. Exemplary values of the pitch P1 are 1 micrometer, 10 micrometers and 40 micrometers. However, it is also possible for the field 103 to have other symmetries, such as a hexagonal symmetry, for example.

A diameter of the beam spots shaped in the first plane 101 can be small. Exemplary values of the diameter are 1 nanometer, 5 nanometers, 10 nanometers, 100 nanometers and 200 nanometers. The focusing of the particle beams 3 for shaping the beam spots 5 is carried out by the objective lens system 100.

The primary particles striking the object generate interaction products, e.g., secondary electrons, back-scattered electrons or primary particles that have experienced a reversal of movement for other reasons, which emanate from the surface of the object 7 or from the first plane 101. The interaction products emanating from the surface of the object 7 are shaped by the objective lens 102 to form secondary particle beams 9. The particle beam system 1 provides a particle beam path 11 for guiding the plurality of secondary particle beams 9 to a detector system 200. The detector system 200 comprises a particle optical unit with a projection lens 205 for directing the secondary particle beams 9 at a particle multi-detector 209.

The excerpt I2 in FIG. 1 shows a plan view of the plane 211, in which individual detection regions of the particle multi-detector 209 on which the secondary particle beams 9 are incident at locations 213 are located. The incidence locations 213 lie in a field 217 with a regular pitch P2 from one another. Exemplary values of the pitch P2 are 10 micrometers, 100 micrometers, and 200 micrometers.

The primary particle beams 3 are produced in a beam generating apparatus 300 comprising at least one particle source 301 (e.g., an electron source), at least one collimation lens 303, a multi-aperture arrangement 305 and a field lens 307. The particle source 301 produces a diverging particle beam 309, which is collimated or at least substantially collimated by the collimation lens 303 in order to shape a beam 311 which illuminates the multi-aperture arrangement 305.

The excerpt I3 in FIG. 1 shows a plan view of the multi-aperture arrangement 305. The multi-aperture arrangement 305 comprises a multi-aperture plate 313, which has a plurality of openings or apertures 315 formed therein. Midpoints 317 of the openings 315 are arranged in a field 319 that is imaged onto the field 103 formed by the beam spots 5 in the object plane 101. A pitch P3 between the midpoints 317 of the apertures 315 can have exemplary values of 5 micrometers, 100 micrometers, and 200 micrometers. The diameters D of the apertures 315 are smaller than the pitch P3 between the midpoints of the apertures. Exemplary values of the diameters D are 0.2×P3, 0.4×P3, and 0.8×P3.

Particles of the illuminating particle beam 311 pass through the apertures 315 and form particle beams 3. Particles of the illuminating beam 311 which strike the plate 313 are absorbed by the latter and do not contribute to the formation of the particle beams 3.

On account of an applied electrostatic field, the multi-aperture arrangement 305 focuses each of the particle beams 3 in such a way that beam foci 323 are formed in a plane 325. Alternatively, the beam foci 323 can be virtual. A diameter of the beam foci 323 can be, for example, 10 nanometers, 100 nanometers and 1 micrometer.

The field lens 307 and the objective lens 102 provide a first imaging particle optical unit for imaging the plane 325, in which the beam foci 323 are formed, onto the first plane 101 such that a field 103 of incidence locations 5 or beam spots arises there. Should a surface of the object 7 be arranged in the first plane, the beam spots are correspondingly formed on the object surface.

The objective lens 102 and the projection lens arrangement 205 provide a second imaging particle optical unit for imaging the first plane 101 onto the detection plane 211. The objective lens 102 is thus a lens that is part of both the first and the second particle optical unit, while the field lens 307 belongs only to the first particle optical unit and the projection lens 205 belongs only to the second particle optical unit.

A beam switch 400 is arranged in the beam path of the first particle optical unit between the multi-aperture arrangement 305 and the objective lens system 100. The beam switch 400 is also part of the second optical unit in the beam path between the objective lens system 100 and the detector system 200.

Further information relating to such multi-beam particle beam systems and components used therein, such as, for instance, particle sources, multi-aperture plate and lenses, can be obtained from the international patent applications WO 2005/024881 A2, WO 2007/028595 A2, WO 2007/028596 A1, WO 2011/124352 A1 and WO 2007/060017 A2 and the German patent applications DE 10 2013 016 113 A1 and DE 10 2013 014 976 A1, the disclosure of which in the full scope thereof is incorporated by reference in the present application.

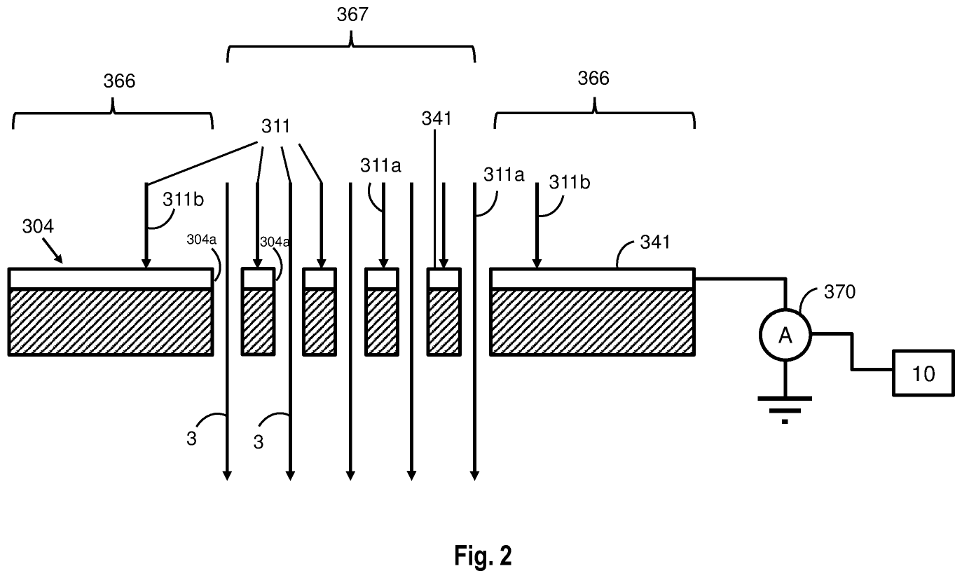

FIG. 2 schematically illustrates a beam current measurement. A multi-aperture array 304 is shown in cross-sectional view. The multi-aperture array 304 comprises on its upper side an absorber layer 341 which can absorb charged particles. In the depicted embodiment, the entire upper side of the multi-aperture array 304 is covered by the absorber layer 341. In the present embodiment, the multi-aperture plate is arranged as the first multi-aperture array downstream of a condenser lens system (not shown in FIG. 2). The illuminating particle beam 311 is incident on the multi-aperture array 304. Most of the incident particles of the illuminating particle beam 311 impinge on the absorber layer 304a and only a small portion of all particles pass through the openings 304a thus generating the plurality of first individual charged particle beams 3. A part of the illuminating particle beam 311 impinges on the outer region 366 of the multi-aperture array 304, exemplarily, particle beams 311b are indicated in FIG. 2. Other portions of the illuminating particle beam 311 impinge on the multi-aperture array 304 in an inner region 367. Some of these particles are indicated exemplarily with a reference sign 311a in FIG. 2. In the present example, the multi-aperture array 304 is not structured. Therefore, all particles impinging on the absorber layer 341 generate excess electrons that are discharged from the absorber layer 341 and are measured by the first beam current measuring mechanism 370 which is embodied as a picoamperemeter in the present case. The measured value is communicated to the control 10 and is used for example for controlling the beam generating system, for example a voltage applied to the extractor electrode or by setting a temperature of the particle source. Other control loops are also possible.

In the example shown only one picoamperemeter is applied which is positioned between the connection to the absorber layer 341 on the one hand and the ground electrode on the other hand. Therefore, the whole area of the absorber layer 341 contributes to the measured value, this comprises a measurement of discharged excess electrons generated by charged particles impinging the multi-aperture array 304 in the outer region 366 as well as in the inner region 367. The depicted principle of measurement is a measurement over a large area which ensures a very good signal-to-noise ratio. In the example shown, an average single beam current of the plurality of the first individual particle beams 3 is equal to or less than 1/1000 of the beam current entirely measured by the first beam current measuring mechanism 370. It is noted that the dimensions in FIG. 2 are not true to scale.

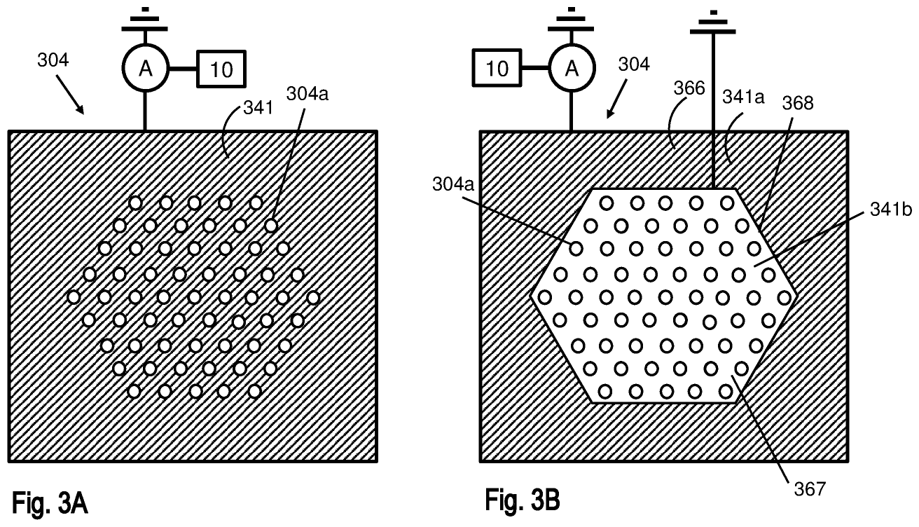

FIGS. 3A-3B schematically illustrate multi-aperture arrays 304 with an absorber layer 341 on its upper side. In FIG. 3A the multi-aperture array 304 as already depicted in FIG. 2 is shown in a top view. It is noted that there is no structuring of the absorber layer 341, but the entire surface of the absorber layer 341 can be used for a measurement of excess electrons.

In contrast thereto, FIG. 3B depicts a multi-aperture plate 304 that is structured into two separate regions that are isolated from one another. The first region is identical with the outer region 366 which is defined as a region around all of the openings 304a in the multi-aperture array 304. The second region is the inner region 367 which comprises all openings 304a in the multi-aperture array 304. In the example shown the plurality of apertures 304a is arranged in a hexagonal way. Therefore, the structuring 368 or the isolation 368 is also provided as a hexagon. Of course, other shapes of an isolation could still be chosen, even if the overall arrangement of apertures 304a is chosen hexagonal. It is for example possible to choose a circle or to choose a rectangle, for example. It is noted that also in FIG. 3B the entire surface of the multi-aperture array 304 is provided with an absorber layer 341, wherein reference sign 341a indicates the absorber layer in the outer region 366 and reference sign 341b indicates the absorber layer in the inner region 367. The absorber layer in the inner region 367 and in the outer region 366 can be chosen to be made from an identical material; however, the material can be also chosen differently. According to an example, the absorber layers can comprise or consist of any one of the following: gold, silver, titanium, platinum. In general, noble metals with a good conductivity can be used.

According to the embodiment depicted in FIG. 3B, both absorber layers 341a and 341b can be connected to ground electrodes, respectively. The excess electrons discharged from the absorber layer 341a are measured by an ammeter 370 in any case. In contrast thereto, a measurement of the excess electrons discharged from the absorber layer 341b with another ammeter is optional. It is noted that there is no further structuring in the inner region 367 of the multi-aperture array 304. Therefore, formation of the plurality of first individual beams 3 is not at all disturbed by the presence of any structuring or electrodes on the multi-aperture array 304.

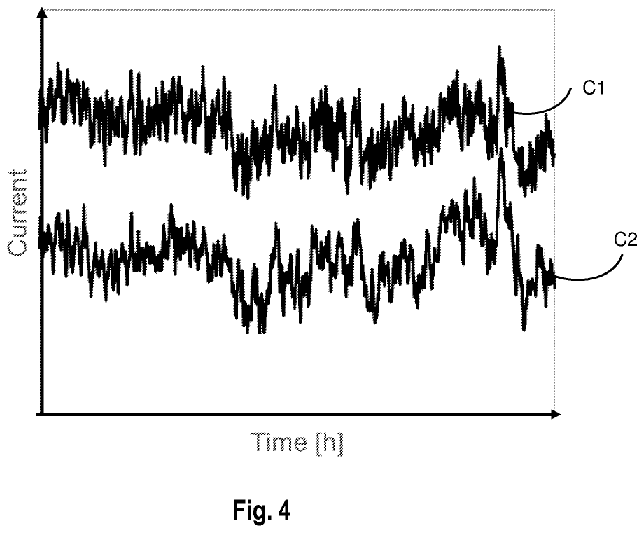

FIG. 4 compares a single beam current and a current generated by excess electrons discharged from an absorber layer 341 of a multi-aperture array 304. The curve indicated by reference sign C1 depicts the current measured with the first beam current measuring mechanism 370. Reference sign C2 indicates a single beam current (shifted in the graph) that was measured for example with a second beam current measuring mechanism, for example via a Faraday cup temporarily put on a stage during a calibration of the entire multi-beam particle microscope. A finding of this comparison is that the variations and fluctuations occurring in the single beam current (curve C2) are also reflected in the curve C1 and thus in a measurement that does not at all target a measurement of a single beam current, but is in general an ensemble measurement. This finding is a decisive base for allowing the change of measurement principle according to the present disclosure: it is not longer the aim to measure as many as possible single beam currents separately with separately provided additional detectors near respective apertures in the multi-aperture array 304. Instead, the target is a measurement with a very good signal-to-noise ratio that can be accomplished by an ensemble measurement and more precisely with a measurement over a large area on the multi-aperture array 304. As a side remark, it is noted that the desired proportionality between the single beam current on the one hand and the measured overall “coating” current cannot automatically be found by large area measurements carried out at other apertures within the system: an ensemble measurement carried out at an extractor aperture or at an aperture of the anode of the source did not show the desired proportionality between the two parameters.

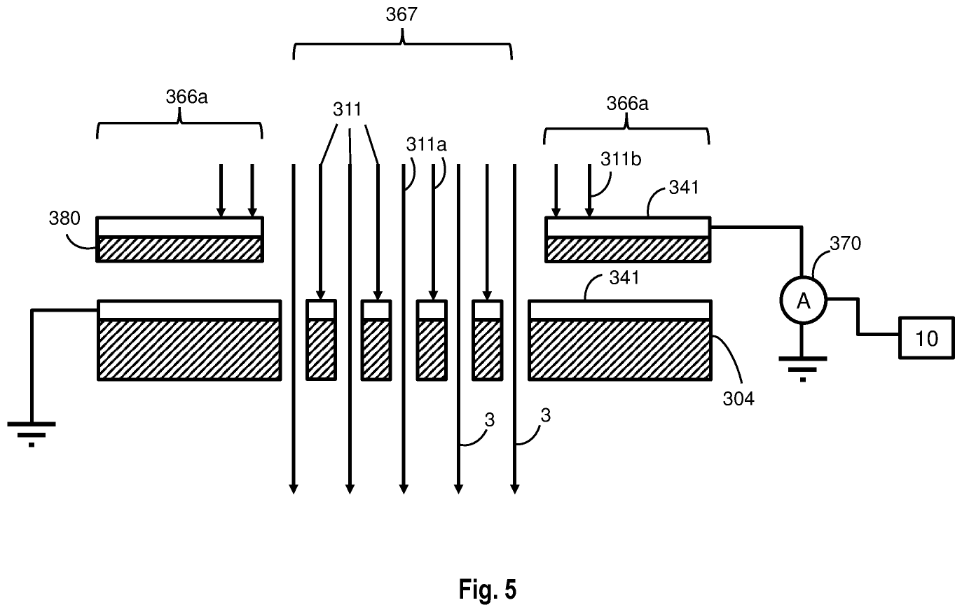

FIG. 5 schematically illustrates another beam current measurement according to another embodiment of the disclosure: in this example, the multi-beam generator comprises a pre-aperture plate 380 and the multi-aperture array 304. As before, the entire surface of the multi-aperture array 304 is covered by an absorber layer 341 which is connected to ground. However, directly upstream of the multi-aperture array 304, the pre-aperture plate 380 is provided. Basically, this pre-aperture plate 380 covers or blocks the outer region 366 of the multi-aperture array 304 and generates its own “outer region” 366a. Particles impinging on the pre-aperture plate 380 are absorbed by the absorber layer 341a and converted into excess electrons that are discharged from the layer 341a and transported to the ground electrode. Within this line to ground, a first beam current measuring mechanism 370 in terms of a single pico amperemeter is provided. The measurement value is communicated to the controller 10. Once again, based on this measurement result, the controller 10 is configured for driving for example the beam generating system or for controlling the condenser lens system. Although this is not depicted in FIG. 5, it is optionally also possible to arrange a further constituent part of the first beam current measuring mechanism 370 in the line leading from the absorber layer 341 to ground and therefore basically to measure excess electrons generated by impinging particles in the inner region 367 onto the multi-aperture array 304 as well.

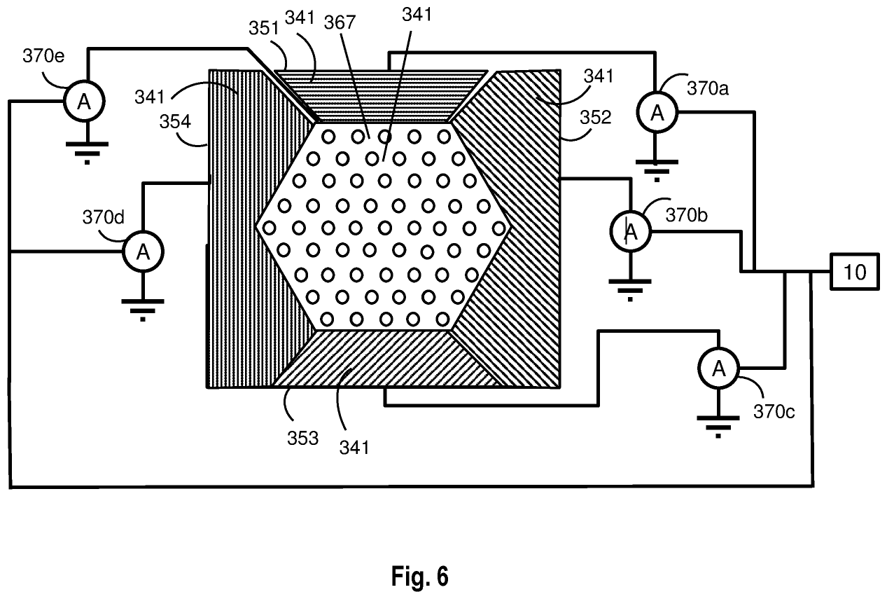

FIG. 6 schematically illustrates a quadrant detector: according to the shown embodiment, the multi-aperture plate 304 is structured into five separate regions 351, 352, 353, 354 and 367 that are isolated from one another. Each region 351, 352, 353, 354 and 367 is connected to ground. The first beam current measuring mechanism 370 comprises five constituent parts 370a, 370b, 370c, 370d and 370e in the embodiment shown. In each case, excess electrons are measured and the measurement result is communicated to the control 10. It is noted that the inner region 367 comprises all openings in the multi-aperture array 304. Therefore, the inner region 367 is not disturbed at all by any structuring or by separately provided detectors. This ensures a very good beam current quality of the generated individual particle beams 3. The outer region 366 is subdivided into the four quadrants 351, 352, 353 and 354. The quadrants 351 and 353 have an area that is identical in size. The same holds for the larger areas of regions 352 and 354. If the beam cone of the illuminating particle beam 311 impinges centered onto the multi-aperture array 304, the signals generated by the measurement of regions 351 and 353 shall indicate the same signal strength. The same holds for signals generated by measurements on the regions 352 and 354. In the different scenario when the beam cone of the illuminating particle beam 311 is shifted into one direction, the signal generated by each quadrant 351, 352, 353 and 354 shows a variation that allows for identifying the direction of the shift. This shift can be corrected, for example by controlling a double deflector in the region of the condenser lens system which allows for parallel shifting of the entire illuminating beam cone 311.

Of course, the quadrant detector depicted in FIG. 6 can in general be realized in a different way. The shape of the quadrants can be changed, so can be the arrangement of apertures itself which is in the present example depicted to be hexagonal.

In general, a directional variation of the entire illuminating beam cone 311 can already be identified by a detector that comprises only three outer regions: an example is a direction indicating tertial detector wherein the outer region 366 is subdivided into three different regions, such as spanning about 120 degrees of the outer region.

Of course, it also possible to further structure the outer region 366 into more than four separate regions. However, it is to be born in mind that any structuring or isolation provided on top of the multi-aperture array 304 bears the potential risk of deteriorating the beam quality of the plurality of first individual particle beams 3 which should be avoided. Furthermore, the bigger the area for a measurement is, the better is the signal-to-noise ratio that can be achieved for this kind of measurement. Optionally, the entire number of separate regions on a multi-aperture array 304 is not bigger than six regions, optionally, it is only exactly four or five separate and isolated regions.

In FIG. 6 the excess electrons stemming from the inner region 367 are measured by the first beam current measuring mechanism 370e. However, this measurement is only optional, it is not necessary in any case to provide a first beam current measuring mechanism 370e. Instead, the central region 367 can only be connected to the ground electrode without any further measurement put in between.

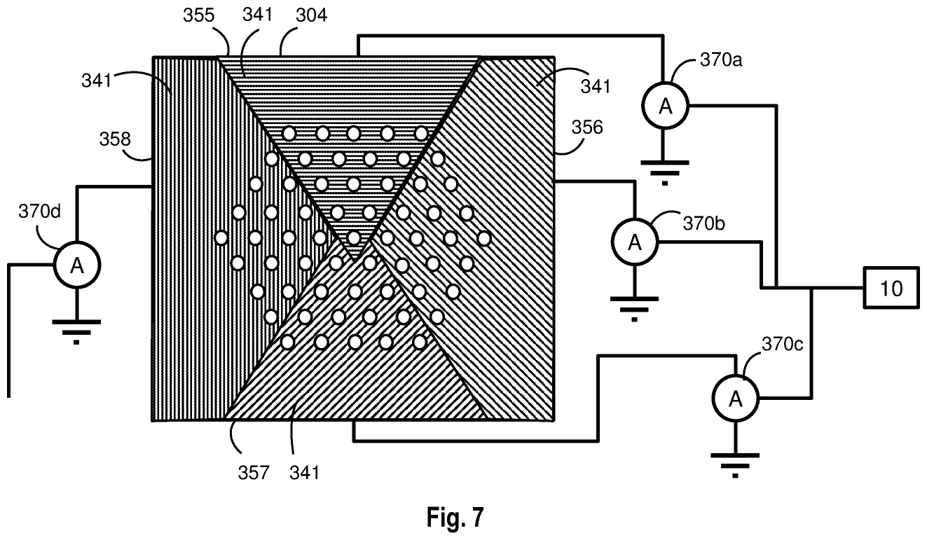

FIG. 7 schematically illustrates another quadrant detector with regions 355, 356, 357 and 358. Once again, the entire surface of the multi-aperture plate 304 is provided with an absorber layer 341. However, the example depicted in FIG. 7 has the disadvantage that there also exists a structuring/isolation within the inner region of the multi-aperture array 304 which bears the risk of unwanted deteriorations of the beam quality of the individual charged particle beams 3. The depicted example is therefore less advantageous, even though the desire to measure over a large area is still met.

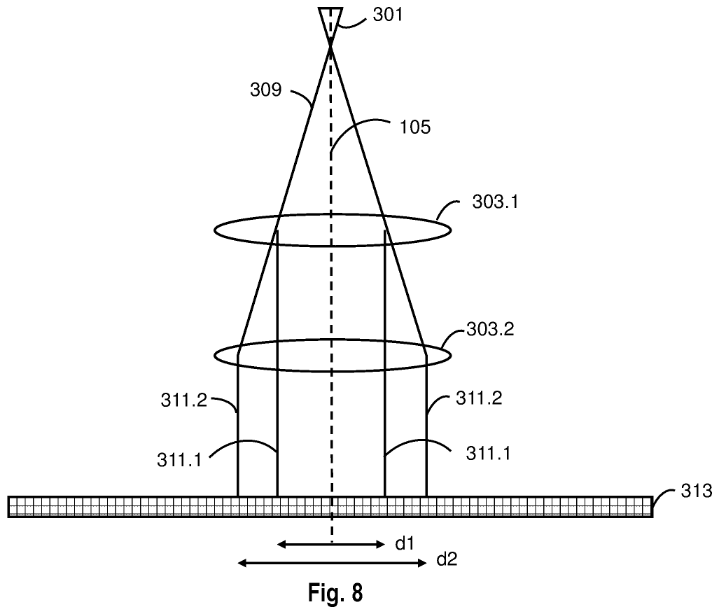

FIG. 8 shows a schematic representation of an adjustment of the beam cone of the illuminating beam 311 upon incidence on a multi-aperture array 313. The beam current per individual particle beam 3 can be adjusted by adjusting the beam cone. Initially, particles or a divergent particle beam 309 are emitted by a source 301. The divergent particle beam 309 passes through a collimation lens system or condenser lens system 303, which comprises two condenser lenses 303.1 and 303.2 in the present example. FIG. 8 now shows two different settings of the condenser lens system 303: In a first setting, the condenser lens 303.1 is activated and the condenser lens 303.2 is deactivated. As a result, the particles of the divergent particle beam 309 are collimated in the condenser lens 303.1 and strike the multi-aperture array 313 as an illuminating particle beam 311.1 with the diameter d1. In the second case, the condenser lens 303.1 is deactivated and the condenser lens 303.2 is activated. Hence, the divergent particle beam 309 expands further and is only collimated in the second condenser lens 303.2 such that an illuminating particle beam 311.2 with the diameter d2 is incident on the multi-aperture plate 313. The number of particles incident on the multi-aperture array 313 is the same in both cases but the density differs. Thus, individual particle beams 3 with different beam current intensities that depend on the diameter of the illumination spot are formed when the multi-aperture array 313 with its openings 315 (not shown) is traversed.

In the example shown, the condenser lenses 303.1 and 303.2 are magnetic lenses in each case. However, it is also possible to replace one or both of the magnetic lenses with an electrostatic condenser lens. Moreover, it is possible to change the number of condenser lenses in the condenser lens system 303 overall, that is to say provide only one lens or else provide three or more lenses. Moreover, one or more deflectors can be provided for the adjustment of the illuminating beam 311. These adjustment approaches and the type of condenser lens(es) have an influence on how quickly the illumination spot can be adjusted. This will be discussed in more detail below, within the scope of this patent application. Initially, all that should be illustrated here is how the different beam currents of the individual particle beams arise when different illumination spots are used.

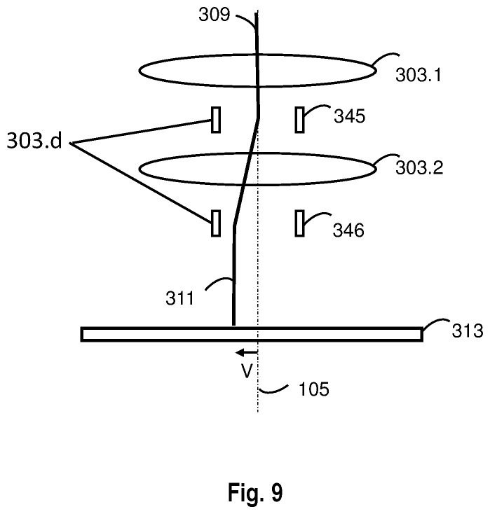

FIG. 9 illustrates further design options for a closed-loop beam current control mechanism. FIG. 9 depicts a ray of the divergent particle beam 309, which runs along the optical axis 105 and was generated via the beam generating system 301. It passes through the condenser lens system 303 having the first condenser lens 303.1 and the second condenser lens 303.2. Each one is a magnetic lens in the depicted example. An electrostatic double deflector with constituent parts 345 and 346 is arranged in the region of the condenser lens system 303. In relation to the particle optical beam path, the constituent part 345 is downstream of the first condenser lens 303.1 and the constituent part 346 is downstream of the second condenser lens 303.2 in the example shown. However, other arrangements of the double deflector in the region of the condenser lens system 303 are possible; by way of example, both constituent parts 345, 346 can be arranged downstream of the second condenser lens 303.2 in relation to the particle optical beam path.

The beam 311 can be offset in parallel by way of the double deflector. Upon incidence on the multi-aperture plate 313, the beam 311 is offset in relation to the optical axis 105 by the vector V. In this case, the electrostatic double deflector 345, 346 can be driven quickly and it is suitable for a high-frequency correction of an offset when the multi-aperture array 313 is illuminated. In turn, the double deflector 345, 346 can be driven on the basis of current values measured via a first beam current measuring mechanism, for example measured via the sensors 370 on the surface of the multi-aperture plate 313. This feedback loop can also be used for fast closed-loop current control during an image recording procedure.

Moreover, it is possible to form one of the condenser lenses 303 as an electrostatic condenser lens 303. This electrostatic condenser lens 303 can also be driven quickly and quasi instantaneously, in order to vary the diameter d of the illumination spot upon incidence on the multi-aperture plate 313 as a result. Once again, driving can be implemented in the form of a feedback loop based on current measurements which, in turn, have been determined for example via sensors 370 on the upper side of the multi-aperture array 313.

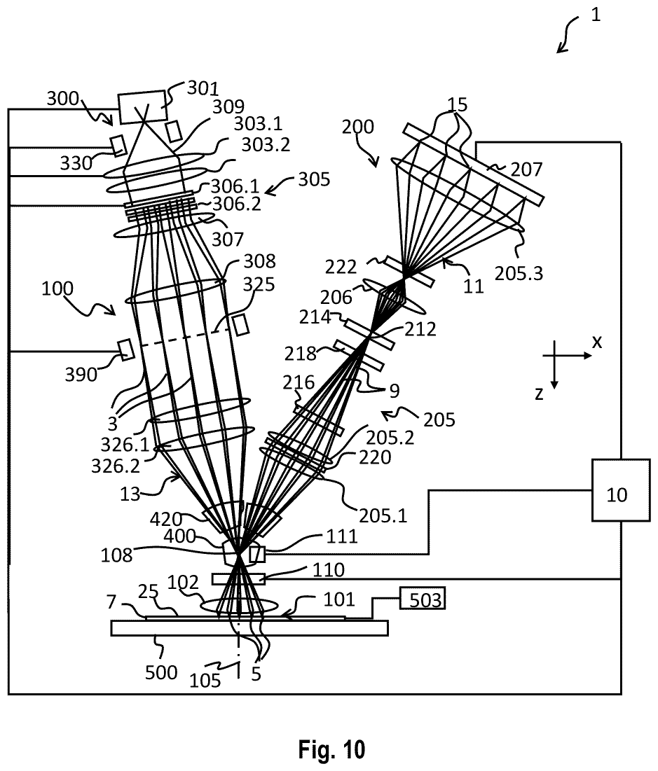

FIG. 10 schematically shows a multi-beam particle microscope 1 having closed-loop beam current control mechanisms and compensators that are driven via a controller 10. The controller 10 can be formed in one part or in many parts, the entire multi-beam particle microscope 1 being able to be controlled via the controller 10. In particular, the controller 10 controls the beam generating system 301, the components of the first particle optical unit, of the second particle optical unit, of the detection system 200 and further components of the multi-beam particle microscope 1, which may or may not be explicitly depicted. In the schematic representation of FIG. 10, only certain control elements and aspects in the context of the present disclosure are represented by connecting lines to selected particle optical components.

Initially, the beam current is measured via various beam current measuring mechanisms and the measured values are transmitted to the controller 10. In the example shown, a first beam current measuring mechanism which is configured to measure at least the discharged excess electrons generated by charged particles impinging the multi-aperture array in an outer region around all of the openings in the multi-aperture array can be connected to the micro-optics 306 comprising a multi-aperture array 313. In this case, this could be a detection arrangement as illustrated in FIG. 2, 3, 5, 6 or 7, for example. Additionally, an overall beam current is measured in the example shown via a sensor system arranged on or assigned to a beam stop 111. In this case, a multi-beam deflector 390 is used to steer the individual particle beams 3 onto the beam stop 111, which is arranged upstream of the objective lens 102 and level with a cross-over plane in the first particle optical beam path. In particular, the controller 10 can be configured to direct the first individual particle beams 3 into the beam stop 111 during a line jump or during an image jump when scanning over a sample surface. Thus, the overall beam current can be measured during an image recording procedure. Alternatively or additionally, the beam current of individual particle beams can be measured using a Faraday cup or an array of Faraday cups provided on the sample stage 503 for calibration purposes.

The components of the multi-beam particle microscope 1 are driven in a manner known per. This includes adjusting the extractor voltage in the beam generating system 301 and also driving the condenser lens system 303. The deflector 330 which is additionally depicted in FIG. 10 serves for static adjustment of the illuminating beam 311 upon incidence on the micro-optics 306. However, the multi-beam particle microscope 1 can comprises further components and control elements for low-frequency or high-frequency driving for the purposes of controlling the beam current:

Additionally or as an alternative, a condenser lens of the condenser lens system 303 can be designed as a fast electrostatic condenser lens and likewise be driven quickly. As a result, it is possible to quickly correct the diameter of the beam incident on the micro-optics 306.

For a fast correction of a lateral offset of the illumination spot, one or more electrostatic deflectors, in particular an electrostatic double deflector as depicted in FIG. 8 for example, may be additionally or alternatively provided in the condenser lens system 303. These deflectors can likewise be driven by way of a feedback signal based on a measured current value via the first beam current measuring mechanism.

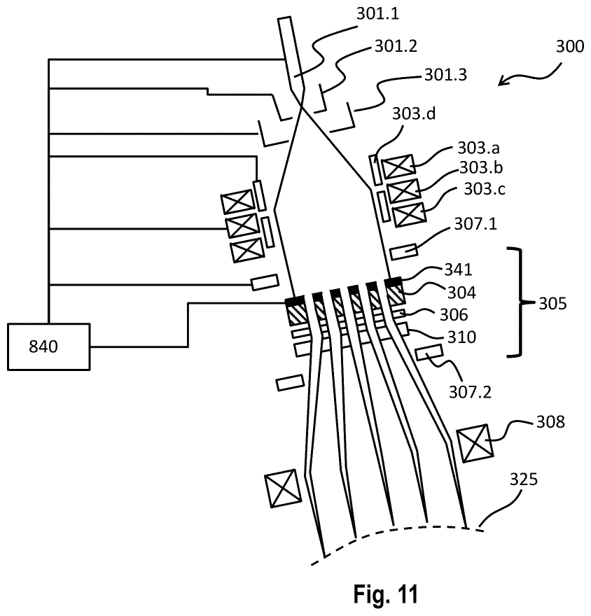

FIG. 11 schematically shows details about a beam current control. More particularly, details of a source control loop are shown. A current monitoring processor 840 is configured for the control loop. The input signal for the control loop is the measurement carried out by the first beam current measuring mechanism which is configured to measure at least the discharged excess electrons generated by charged particles impinging the multi-aperture array 304 in an outer region around all of the openings in the multi-aperture array 304. The first beam current measuring mechanism which can be embodied by an ammeter and in particular a picoammeter is not shown in FIG. 11. However, schematically, the absorber layer 341 provided on the upper side of the multi-aperture array 304 is shown. The multi-aperture array 304 is part of the multi-aperture arrangement 305 which furthermore comprises a second multi-aperture 306 plate which can, for example, comprise a lens array, a deflector array and/or a stigmator array as well as a final multi-aperture plate 310. Other configurations are also possible.

The current monitoring processor 840 is part of the entire control 10 of the multi-beam particle microscope 1. The current monitoring processor 840 is configured for controlling the beam generating system 301 and/or the condenser lens system 303 on the basis of the measurement via the first beam current measuring mechanism 370. Other particle optical components can be controlled as well.

The beam generating system 301 comprises several parts. In the example shown, the beam generating system 301 comprises a source tip 301.1, a suppressor electrode 301.2 and an extractor electrode 301.3. The current monitoring processor 840 can for example be configured for controlling the beam generating device 301 by setting a voltage supplied to the extractor electrode 301.3. Additionally or alternatively, the controller 840 can be configured for controlling the beam generating device 301 by setting a temperature of a particle source 301.1, in particular by setting a heating current or heating voltage. Additionally or alternatively, a voltage supplied to the suppressor electrode 301.2 can be set.

Additionally or alternatively, the controller 840 can control the condenser lens system 303 which comprises in the present case three condenser lenses 303.a, 303.b and 303.c. They can be controlled for setting the focal length and also for setting the diameter of the illuminating particle beam 311 impinging on the multi-aperture arrangement 304 and more precisely impinging on the first multi-aperture array 304 in the example shown.

In the depicted embodiment, a double deflector 303.d, in particular an electrostatic double deflector 303.d, is provided in the region of the condenser lens system 303. The controller 840 is configured to control the double deflector 303.d on the basis of the measurement via the first beam current measuring mechanism 370.

Optionally, the controller 840 can also control the electrode 307.1 generating an immersion field in the first multi-aperture array 304. Optionally, a controlled multi-pole electrode for tilt correction can also be provided and controlled by the controller 840.

According to the above-described embodiments, the controlled variable in each case is a current generated by of the discharged excess electrons, the discharged excess electrons being generated by charged particles impinging the multi-aperture array 304 in an outer region 366 around all of the openings in the multi-aperture array 304. However, it is also possible to use another controlled variable which is not the current generated by discharged excess electrons: according to an alternative solution, the controlled variable is an X-ray detection.

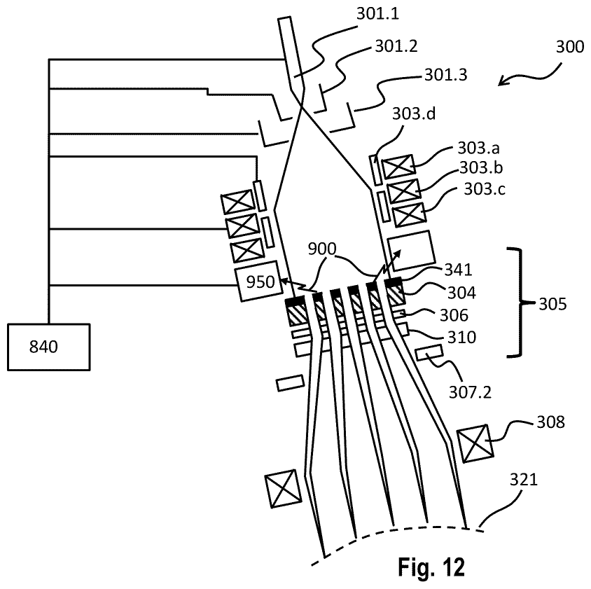

FIG. 12 schematically illustrates details of another beam current control based on a measurement of X-rays 900. In the depicted embodiment, an X-ray detector 950 is provided instead of the amperemeters measuring discharged excess electrons. The X-rays 900 are generated by the charged particles impinging the absorber layer 341 on the upper side of the multi-aperture array 304. Experiments carried out by the inventors have shown that the amount of X-rays or number of X-ray photons measured by the X-ray detector 950 is proportional to the beam current of the first individual particle beams striking the sample at incidence locations. In the present case, the X-ray detector 950 is provided as a ring-shaped scintillator element in the circumference of the multi-aperture array 304. By this arrangement a good signal-to-noise ratio can be achieved. The controller 840 is then configured to control the beam generating system 301 on the basis of the measurement via the X-ray detector 950. The remaining elements of the current control by X-ray detection are identical with the elements already depicted and further described in FIG. 11; the same reference signs indicate the same elements. In order to avoid superfluous repetitions, explicit reference is made to FIG. 11 for further explanations.

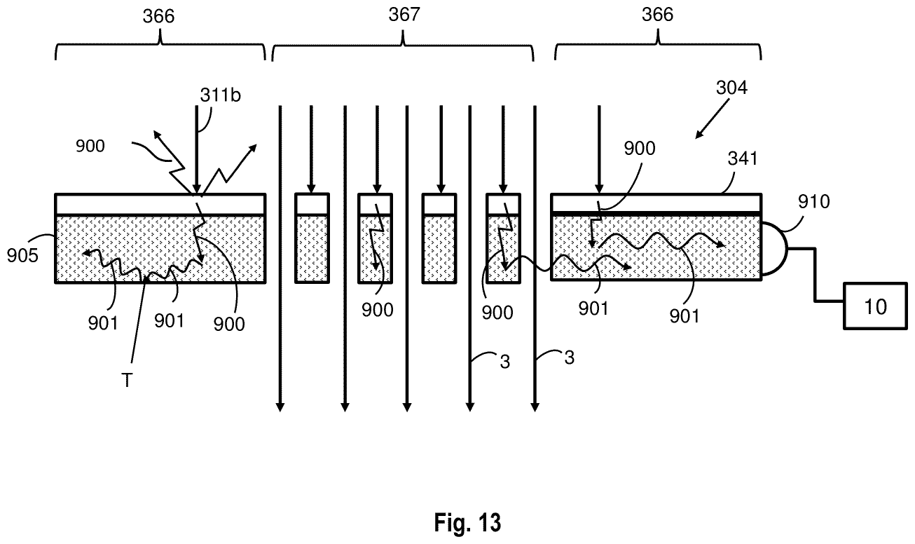

FIG. 13 schematically illustrates another realization of a beam current measuring mechanism using X-rays 900 converted into NIR (near infrared) radiation. In the depicted example, the multi-aperture array 304 comprises a quartz plate 905 that is coated with the absorber layer 341. Instead of the quartz plate 905 other plates made from transparent materials can be used, such as PMMA, for example. The quartz plate is doped with a fluorescent material which serves as a scintillator. Charged particles such as electrons impinging the absorber layer 341 are converted into X-rays 900 first. Inside the quartz plate 905, the X-rays 900 are converted into photons or near infrared radiation 901. The photons 901 are guided inside the quartz plate 905 by internal reflection and are finally detected by one or more light detectors 910 arranged at the periphery of the quartz glass plate 905. By way of example, a point T at which total reflection of the photons 901 occurs is depicted in FIG. 13. The signals measured by the one or more light detectors 910 are communicated to the controller 10 (or its component 840, for example) and are used for controlling the beam generating system 301 and/or the condenser lens system 303. The other kinds of control schematically shown in FIG. 12 can also be carried out. Explicit reference is made to FIG. 12 and also to FIG. 11 in this respect.

Also according to this embodiment, the desired proportionality between the beam current of the individual particle beams striking the sample on the one hand and the near infrared radiation detected via the light detectors 910 shows the proportionality.

A multi-beam particle microscope with improved beam current control is disclosed. Excess electrons discharged from one or just a few regions of an absorber layer provided on a multi-aperture array are measured via an ammeter. The measured currents are used as controlled variables in a closed loop control. The measurement is large-area and low-noise. The multi-aperture array can be specifically structured to also realize a direction sensitive detection, for example via a quadrant detector or a tertial detector.

### Example 1

A multi-beam particle microscope, comprising the following:
a beam generating system comprising a particle source, an extractor electrode and an anode and configured to produce a first charged particle beam;
a multi-beam generator having a multi-aperture array, the multi-beam generator being configured to produce a first field of a plurality of first individual charged particle beams from the first charged particle beam, the multi-aperture array comprising on its upper side an absorber layer which absorbs charged particles, the absorber layer being connected to at least one ground electrode to discharge excess electrons;
an X-ray detector configured to detect X-rays generated by the charged particles impinging the absorber layer of the multi-aperture array;
a first particle optical unit with a first particle optical beam path, configured to direct the generated first individual particle beams at a sample such that the first individual particle beams strike the sample at incidence locations, which form a second field;
a detection system;
a second particle optical unit with a second particle optical beam path, which is configured to image second individual particle beams, which emanate from the incidence locations in the second field, onto the detection system;
a particle optical objective lens, through which both the first and the second individual particle beams pass;
a beam switch, which is arranged in the first particle optical beam path between the multi-beam particle source and the objective lens and which is arranged in the second particle optical beam path between the objective lens and the detection system; and
a controller which is configured to control the beam generating system, the particle optical objective lens, the first particle optical unit, the second particle optical unit, and the detection system, and
with the controller being configured for driving of the beam generating system on the basis of the measurement via the X-ray detector, and/ or
with the controller being configured for controlling the condenser lens system on the basis of the measurement via X-ray detector.

### Example 2

The multi-beam particle microscope according to example 1, wherein the X-ray detector is provided as a ring-shaped scintillator element upstream of and in the circumference of the multi-aperture array.

### Example 3

A multi-beam particle microscope, comprising the following:
a beam generating system comprising a particle source, an extractor electrode and an anode and configured to produce a first charged particle beam;
a multi-beam generator having a multi-aperture array, the multi-beam generator being configured to produce a first field of a plurality of first individual charged particle beams from the first charged particle beam, the multi-aperture array comprising on its upper side an absorber layer which absorbs charged particles, the absorber layer being connected to at least one ground electrode to discharge excess charged particles;
an X-ray conversion mechanism for converting X-rays generated by the charged particles impinging the absorber layer of the multi-aperture array into NIR radiation;
a light guide for guiding the NIR radiation to a light detector;
the light detector configured for detecting NIR radiation
a first particle optical unit with a first particle optical beam path, configured to direct the generated first individual particle beams at a sample such that the first individual particle beams strike the sample at incidence locations, which form a second field;
a detection system;
a second particle optical unit with a second particle optical beam path, which is configured to image second individual particle beams, which emanate from the incidence locations in the second field, onto the detection system;
a particle optical objective lens, through which both the first and the second individual particle beams pass;
a beam switch, which is arranged in the first particle optical beam path between the multi-beam particle source and the objective lens and which is arranged in the second particle optical beam path between the objective lens and the detection system; and
a controller which is configured to control the beam generating system, the particle optical objective lens, the first particle optical unit, the second particle optical unit, and the detection system, and
with the controller being configured for driving of the beam generating system on the basis of the measurement via the light detector, and/ or
with the controller being configured for controlling the condenser lens system on the basis of the measurement via the light detector.

### Example 4

The multi-beam particle microscope according to example 3,
wherein the light guide comprises a quartz glass plate doped with a scintillating material for converting X-rays into NIR radiation; and
wherein the light detector is arranged at the periphery of the quartz glass plate.

### LIST OF REFERENCE SIGNS

1 Multi-beam particle microscope
3 Primary particle beams (individual particle beams)
5 Beam spots, incidence locations
7 Object
9 Secondary particle beams
10 Computer system, controller
11 Secondary particle beam path
13 Primary particle beam path
25 Sample surface, wafer surface
100 Objective lens system
101 Object plane
102 Objective lens
103 Field
105 Optical axis of the multi-beam particle microscope
108 Cross-over
110 Collective scan deflector
111 Beam stop with a second current measuring mechanism
200 Detector system
205 Projection lens
207 Detection region
208 Deflector for adjustment purposes
209 Particle multi-detector
211 Detection plane
212 Cross-over
213 Incidence locations
214 Aperture filter
215 Detection region
216 Active element
217 Field
218 Deflector system
220 Multi-aperture corrector, individual deflector array
222 Collective deflection system, anti-scan
300 Beam generating apparatus
301 Particle source, beam generating system
303 Collimation lens system
304 multi-aperture array
304a opening
305 Multi-aperture arrangement
306 Micro-optics
307 Field lens
308 Field lens
309 Diverging particle beam
311 Illuminating particle beam
313 Multi-aperture plate, multi-aperture array
315 Openings in the multi-aperture plate
316 Hexagon
317 Midpoints of the openings
319 Field
323 Beam foci
325 Intermediate image plane
326 Field lens system
330 Deflector
340 Tip
341 absorber layer
342 Extractor electrode
343 Anode
345 Deflector
346 Deflector
351 Region
352 Region
353 Region
354 Region
360 Beam current intensity representation
366 outer region
367 inner region
368 structuring, isolation
370 First beam current measuring mechanism, ammeter, picoampere meter
380 pre-aperture plate
390 Multi-beam deflector
400 Beam switch
420 Magnetic element
500 Sample stage
503 Voltage supply for the sample
900 X-ray
901 Photon, NIR radiation
905 Quartz plate
910 Light detector
950 X-ray detector
d1 Beam cone diameter
d2 Beam cone diameter
V Displacement between beam cone midpoint and multi-aperture array midpoint
T point of total reflection

What is claimed is:

1. A multi-beam particle microscope, comprising:
a beam generating system comprising a particle source, an extractor electrode and an anode, the beam generating system configured to produce a first charged particle beam;
a multi-beam generator comprising a multi-aperture array, the multi-beam generator configured to produce a first field of a plurality of first individual charged particle beams from the first charged particle beam, a first side of the multi-aperture array comprising an absorber layer configured to absorb charged particles, the absorber layer connected to a ground electrode to discharge excess electrons;
a first beam current measuring mechanism configured to measure the discharged excess electrons generated by charged particles impinging on the multi-aperture array in an outer region around the openings in the multi-aperture array;
a condenser lens system between the beam generating system and the multi-beam generator;
a first particle optical unit having a first particle optical beam path, the first particle optical unit configured to direct the first individual particle beams at a sample so that the first individual particle beams strike the sample at incidence locations, which form a second field;
a detection system;
a second particle optical unit having a second particle optical beam path, the second particle optical unit configured to image second individual particle beams, which emanate from the incidence locations in the second field, onto the detection system;
a particle optical objective lens configured to have the first and the second individual particle beams pass therethrough;
a beam switch in the first particle optical beam path between the multi-beam generator and the objective lens, the beam switch in the second particle optical beam path between the objective lens and the detection system; and
a controller configured to control the beam generating system, the condenser lens system, the particle optical objective lens, the first particle optical unit, the second particle optical unit, and the detection system,
wherein the controller is configured to control:
the beam generating system based on a measurement made using the first beam current measuring mechanism; and/or
the condenser lens system based on a measurement made using the first beam current measuring mechanism.

2. The multi-beam particle microscope of claim 1, wherein the first beam current measuring mechanism is configured to measure the discharged excess electrons generated by charged particles impinging on the multi-aperture array in an inner region comprising the openings in the multi-aperture array.

3. The multi-beam particle microscope of claim 1, wherein:
the absorber layer comprises exactly two separate regions that are isolated from one another;
each of the exactly two regions of the absorber layer are connected to ground;
a first region of the exactly two regions of the absorber layer is an inner region comprising the openings of the multi-aperture array;
a second region of the exactly two regions of the absorber layer is the outer region around all of the openings in the multi-aperture array; and
the first beam current measuring mechanism is configured to measure the excess charged particles discharged only from the second region.

4. The multi-beam particle microscope of claim 1, wherein:
the absorber layer comprises two separate regions isolated from one another;
each of the two regions is connected to ground; and
the first beam current measuring mechanism is configured to measure the excess electrons discharged from each region separately.

5. The multi-beam particle microscope of claim 4, wherein:
the absorber layer comprises an inner region and an outer region;
the inner region comprises the openings of the multi-aperture array;
the outer region is around all of the openings in the multi-aperture array;
the outer region comprises four separate regions defining a direction indicating quadrant detector; and
the first beam current measuring mechanism is configured to measure the excess electrons discharged from each of the four regions separately.

6. The multi-beam particle microscope of 4, wherein:
the absorber layer comprises an inner region and an outer region;
the outer region comprises three separate regions configured to define a direction indicating tertial detector; and
the first beam current measuring mechanism is configured to measure the excess electrons discharged from each of the three regions separately.

7. The multi-beam particle microscope of claim 1, further comprising a double deflector in a region of the condenser lens system, wherein the controller is configured to control the double deflector based on the measurement made using the first beam current measuring mechanism.

8. The multi-beam particle microscope of claim 1, wherein the first beam current measuring mechanism comprises an ammeter.

9. The multi-beam particle microscope of claim 1, wherein at least 60% of the beam current reaching the multi-aperture array is used for the beam current measurement.

10. The multi-beam particle microscope of claim 1, wherein at least 90% of the beam current reaching the multi-aperture array is used for the beam current measurement.

11. The multi-beam particle microscope of claim 1, wherein an active beam measurement surface of the absorber layer is configured to absorb charged particles and to discharge electrons for the beam current measurement, and the active beam measurement surface is at least 60% of an entire area of the first surface of the multi-aperture array.

12. The multi-beam particle microscope of claim 1, wherein an active beam measurement surface of the absorber layer is configured to absorb charged particles and to discharge electrons for the beam current measurement, and the active beam measurement surface is at least 90% of an entire area of the first surface of the multi-aperture array.

13. The multi-beam particle microscope of claim 1, wherein the multi-beam particle microscope is configured so that, during use, an average single beam current of the plurality of the first individual particle beams is at most 1% of the entire beam current measured by the first beam current measuring mechanism.

14. The multi-beam particle microscope of claim 1, wherein:
the absorber layer comprises an absorber coating; and/or
the absorber layer comprises at least one member selected from the group consisting of gold, silver, titanium, and platinum.

15. The multi-beam particle microscope of claim 1, wherein the multi-aperture array is a first multi-aperture array downstream of the condenser lens system, and the multi-aperture array is configured to divide the first charged particle beam into the plurality of first individual particle beams.

16. The multi-beam particle microscope of claim 1, wherein the multi-aperture array is not a first multi-aperture array downstream of the condenser lens system.

17. The multi-beam particle microscope of claim 1, wherein the controller is configured to set a voltage supplied to the extractor electrode to control the beam generating device.

18. The multi-beam particle microscope of claim 1, wherein the controller is configured to set a temperature of the particle source to control the beam generating device.

19. A multi-beam particle microscope, comprising:
a beam generating system comprising a particle source, an extractor electrode and an anode, the beam generating system configured to produce a first charged particle beam;
a multi-beam generator comprising a pre-aperture plate and a multi-aperture array, the multi-beam generator configured to produce a first field of a plurality of first individual charged particle beams from the first charged particle beam, the multi-aperture array downstream and adjacent to the pre-aperture plate, a first side of the multi-aperture array comprising an absorber layer configured to absorb charged particles, the absorber layer connected to a ground electrode to discharge excess electrons, a first side of the pre-aperture plate comprising a pre-aperture plate absorber layer configured to absorb charged particles, the pre-aperture plate absorber layer connected to a ground electrode to discharge excess electrons;
a first beam current measuring mechanism configured to measure the discharged excess electrons generated by charged particles impinging on the pre-aperture plate;
a condenser lens system between the beam generating system and the multi-beam generator;
a first particle optical unit having a first particle optical beam path, the first particle optical unit configured to direct the first individual particle beams at a sample so that the first individual particle beams strike the sample at incidence locations, which form a second field;
a detection system;
a second particle optical unit having a second particle optical beam path, the second particle optical unit configured to image second individual particle beams, which emanate from the incidence locations in the second field, onto the detection system;
a particle optical objective lens configured to have the first and the second individual particle beams pass therethrough;
a beam switch in the first particle optical beam path between the multi-beam particle source and the objective lens, the beam switch in the second particle optical beam path between the objective lens and the detection system; and
a controller configured to control the beam generating system, the particle optical objective lens, the first particle optical unit, the second particle optical unit, and the detection system,
wherein the controller is configure to:
drive the beam generating system based on a measurement made using the first beam current measuring mechanism; and/ or
control the condenser lens system based on a measurement made using the first beam current measuring mechanism.

20. The multi-beam particle microscope of claim 19, further comprising a double deflector in a region of the condenser lens system, wherein the controller is configured to control the double deflector based on the measurement made using the first beam current measuring mechanism.
